(19) United States
(12) Patent Application Publication
(10) Pub. No.: US 2010/0227451 A1
(43) Pub. Date: Sep. 9, 2010

(54) Method for manufacturing semiconductor device

(75) Inventor: Kazushi Suzuki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/656,891

(22) Filed: Feb. 18, 2010

(30) Foreign Application Priority Data
Mar. 6, 2009 (JP) 2009-053189

(51) Int. Cl. H01L 21/76

(52) U.S. Cl. 438/401; 257/E21.54

(57) ABSTRACT

A semiconductor device manufacturing method includes: forming an element-isolating insulating film in an element-forming region, and an underlying insulating film in a peripheral region; forming a gate material film; etching the gate material film to form a gate pattern and removing the gate material film on the underlying insulating film to form an alignment mark-forming region; forming an interlayer insulating film; etching the interlayer insulating film to form a contact hole, and a mark hole in the alignment mark-forming region; forming a first conductive film so as to fill the contact hole but not to fill the mark hole; removing the first conductive film outside the contact hole and the mark hole; forming a second conductive film so as not to fill the mark hole; and performing lithographic alignment by taking advantage of a level difference created by a recess left inside the mark hole.

### BACKGROUND OF THE INVENTION

1. Field of the Invention

The present invention relates to a method for manufacturing a semiconductor device.

2. Description of Related Art

In a lithography process of a semiconductor device manufacturing process, an alignment mark on a wafer is optically read and an alignment mark on a mask is positionally aligned with this alignment mark on the wafer when a mask pattern is transferred onto the wafer.

As a method for forming the alignment mark on the wafer, Japanese Patent Laid-Open No. 11-74174 describes the following method explained using FIGS. 1 and 2 of the document. First, an interlayer insulating film is formed on a semiconductor substrate on which elements are provided. A contact hole is formed in this interlayer insulating film and, at the same time, a groove narrower in width and shallower in depth than this contact hole is formed therein. Next, a barrier metal film is formed inside the contact hole and, at the same time, the opening of the groove is blocked up so that a hollow part remains inside the groove. Next, a plug material is film-formed to fill the contact hole. Next, chemical-mechanical polishing (CMP) is performed to remove the plug material and barrier metal outside the contact hole, thereby forming a contact plug and, at the same time, exposing the opening of the groove. Next, an interconnect material is deposited across the entire surface of the semiconductor substrate, and then photoresist is coated thereon. Next, the alignment of an interconnect-forming photomask is performed using a recess created on a surface of the photoresist on the opening of the groove as an alignment mark, and the photoresist is subjected to patterning. Using this patterned photoresist as a mask, interconnects are formed. Japanese Patent Laid-Open No. 11-74174 describes that according to this method, it is possible to precisely form a fine groove for an alignment mark in the interlayer insulating film.

In addition, Japanese Patent Laid-Open No. 11-74174 describes the following method explained as related art using FIGS. 3 and 4 of this document. First, an interlayer insulating film is formed on a semiconductor substrate in which elements and an element-isolating insulating film are provided. A contact hole is formed in this interlayer insulating film and, at the same time, an alignment groove not reaching the substrate but reaching the element-isolating insulating film and deeper than the contact hole is formed. Next, a barrier metal film and a tungsten film are sequentially formed to fill the contact hole and the alignment groove. At this time, a level difference is formed in the tungsten film on the alignment groove since the alignment groove is wider than the opening of the contact hole. Next, the tungsten film is etched back to remove the tungsten film and the barrier metal film outside the contact hole, thereby forming a contact plug. Although the tungsten film and the barrier metal film inside the alignment groove also remain at this time, upper portions of the remaining films inside the groove are removed according to this level difference and, thus, a level difference is formed in the opening of the alignment groove. Next, a wiring metal film is formed and subjected to patterning. At that time, a recess is formed in the wiring metal film due to the effect of the level difference. This recess is utilized to perform alignment in a photolithography process.

As another method for forming an alignment mark on a wafer, Japanese Patent Laid-Open No. 2008-41994 describes the following method explained using FIGS. 2 to 5 of the document. First, a gate insulating film and a gate multilayer film including a plurality of conductive films are formed on a semiconductor substrate in which element-isolating insulating film is provided. Next, this gate multilayer film is patterned into a gate shape and, at the same time, the gate multilayer film in an alignment mark-forming region in which an alignment mark is to be formed later is selectively removed, thereby forming a concave portion in which the element-isolating insulating film is exposed. After going through processes necessary to form elements, an alignment mark (convex portion) is formed inside this concave portion. Next, an interlayer insulating film is formed so as to fill this concave portion. A via hole is formed in this interlayer insulating film and, at the same time, the interlayer insulating film of the alignment mark-forming region (corresponding to the concave portion) is removed. In addition, the element-isolating insulating film around the alignment mark (convex portion) is removed or thinned to form a concave portion. As a result, an alignment mark (convex portion) is formed inside this concave portion, the convex portion (level difference) is larger in height. Next, a conductive film is formed so as to fill the via hole (at that time, the concave portion is not filled with the conductive film). Then, chemical-mechanical polishing (CMP) is performed to remove the conductive film outside the via hole and form a plug (at that time, the conductive film remains inside the concave portion). Next, a conductive film for wiring is formed and subjected to patterning using a photolithography technique and a dry etching technique to form wirings. At that time, alignment in a photolithography process is performed using the alignment mark inside this concave portion. The patent document describes that the alignment mark formed by this method is not affected by a CMP process since an adequate distance is provided between the upper surface of the alignment mark (upper surface of the convex portion) and the upper surface of the interlayer insulating film. In addition, the patent document states that it is possible to accurately and securely detect the alignment mark since an adequate level difference is secured between the upper surface of this alignment mark and the periphery thereof (bottom face of the concave portion).

### SUMMARY OF THE INVENTION

In a semiconductor device manufacturing method, there is a demand for simply and conveniently forming an accurately detectable alignment mark.

In one embodiment, there is provided a semiconductor device manufacturing method including:

forming an element-isolating insulating film in an element-forming region of a semiconductor substrate and forming an underlying insulating film in a peripheral region outside the element-forming region;

forming a gate material film on the element-forming region and the peripheral region;

etching the gate material film to form a gate pattern in the element-forming region and removing the gate material film on the underlying insulating film to form an alignment mark-forming region in the peripheral region;

forming an interlayer insulating film on the element-forming region and the alignment mark-forming region;

etching the interlayer insulating film to form a contact hole penetrating the interlayer insulating film in the element-forming region and to form a mark hole penetrating the interlayer insulating film in the alignment mark-forming region;

forming a first conductive film so as to fill the contact hole but not to fill the mark hole;

removing the first conductive film outside the contact hole and the mark hole to form a contact plug inside the contact hole and leave a recess inside the mark hole;

forming a second conductive film so as not to fill the recess inside the mark hole, whereby leaving a recess inside the mark hole; and

performing lithographic alignment by taking advantage of a level difference created by the recess inside the mark hole after the formation of the second conductive film to pattern the second conductive film.

In another embodiment, there is provided the semiconductor device manufacturing method, wherein the forming the element-isolating insulating film and the underlying insulating film includes:

forming a first concave portion in the element-forming region of the semiconductor substrate and forming a second concave portion surrounding a surface part of the semiconductor substrate in the peripheral region such that the surface part of the semiconductor substrate remains inside the bottom-side opening of the mark hole;

forming an insulating film so as to fill the first concave portion and the second concave portion; and

removing the insulating film outside the first concave portion and the second concave portion by performing chemical-mechanical polishing, whereby forming the element-isolating insulating film with the insulating film left inside the first concave portion and forming the underlying insulating film with the insulating film left inside the second concave portion; and

wherein the mark hole is formed such that the surface part of the semiconductor substrate is located inside the bottom-side opening of the mark hole.

According to an embodiment, it is possible to provide a semiconductor device manufacturing method capable of simply and conveniently forming an accurately detectable alignment mark to enable high-accuracy alignment.

### BRIEF DESCRIPTION OF THE DRAWINGS

The above features and advantages of the present invention will be more apparent from the following description of certain preferred embodiments taken in conjunction with the accompanying drawings, in which:

FIGS. 1A and 1B each show an explanatory drawing illustrating an alignment mark according to a first exemplary embodiment;

FIGS. 2A to 2C each show an explanatory drawing illustrating an alignment mark according to a second exemplary embodiment;

FIGS. 3A to 3E each show an explanatory drawing illustrating a method for forming an alignment mark according to the first exemplary embodiment;

FIG. 4 shows a partial cross-sectional view of an alignment mark according to a related art; and

FIG. 5 shows a partial cross-sectional view of an alignment mark according to another related art.

### DETAILED DESCRIPTION OF THE PREFERRED EMBODIMENTS

Now, exemplary embodiments will be described using the accompanying drawings.

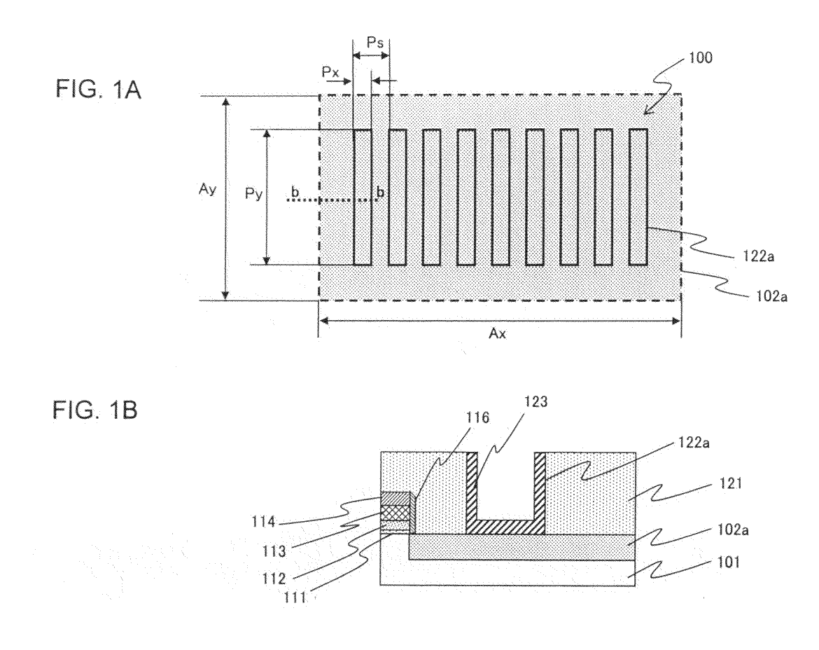

FIGS. 1A and 1B are explanatory drawings illustrating an alignment mark according to a first exemplary embodiment. FIG. 1A illustrates a layout of mark holes composing the alignment mark and FIG. 1B is a partial cross-sectional view (cross section viewed along the line b-b of FIG. 1A) illustrating one mark hole. In the figures, reference numeral 100 denotes an alignment mark, reference numeral 101 denotes a silicon substrate, reference numeral 102a denotes an underlying insulating film, reference numeral 111 denotes a gate oxide film, reference numeral 112 denotes a DOPOS (Doped poly-Silicon) film, reference numeral 113 denotes a tungsten (W) film, reference numeral 114 denotes a gate mask nitride film, reference numeral 116 denotes a sidewall nitride film, reference numeral 121 denotes an interlayer insulating film, reference numeral 122a denotes a mark hole, and reference numeral 123 denotes a DOPOS film.

As illustrated in FIG. 1A, the alignment mark 100 according to the present exemplary embodiment includes a plurality of mark holes 122a identical in shape. The mark holes, each having a rectangular opening shape (planar shape), are arranged at equal spaces, so that the long sides of the respective opening shapes are parallel to one another. In addition, the both longitudinal ends of the respective mark holes are aligned with one another. The alignment mark may include one mark hole only. However, higher alignment accuracy can be obtained by allowing the alignment mark to include a plurality of mark holes.

As illustrated in FIG. 1B, the mark holes 122a composing the alignment mark 100 are provided in the interlayer insulating film 121 of a peripheral region outside an element-forming region. The mark holes 122a composing the same alignment mark have depths identical to one another.

In addition, as illustrated in FIG. 1B, each mark hole 122a is formed in a region (alignment mark-forming region) from which the gate multilayer film (gate material film) including the DOPOS film 112, the W film 113 and the gate mask nitride film 114 has been removed.

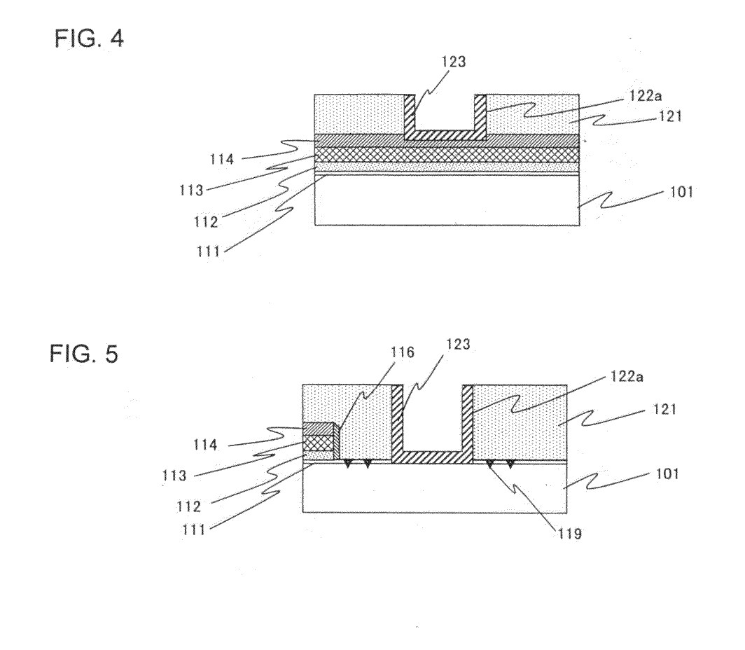

As a comparative example for such a structure of the present exemplary embodiment, FIG. 4 illustrates a structure in which a mark hole is formed on a gate multilayer film. A comparison of this comparative example with the present exemplary embodiment shows that it is possible to form mark holes according to the present exemplary embodiment all the more deep because of the absence of the gate multilayer film. A level difference between the bottom of a concave portion formed inside the mark hole and the peripheral part of the opening of the concave portion becomes larger with an increase in the depth of each mark hole. Accordingly, the contrast of a peripheral border of the mark at the time of alignment is enhanced and, therefore, higher alignment accuracy can be obtained.

In addition, in the present exemplary embodiment, the underlying insulating film 102a is provided in the silicon substrate 101 in a region of the peripheral region in which mark holes are formed, and the gate multilayer film (112, 113 and 114) on this underlying insulating film 102a is removed. As described above, the mark holes are formed in the interlayer insulating film within this region (alignment mark-forming region) from which the gate multilayer film has been removed. This alignment mark-forming region is preferably a region from which a part of the gate multilayer film corresponding to a region defined by a peripheral border of the underlying insulating film 102a in a planar substrate surface, or a part of the gate multilayer film within that region, has been removed.

As a comparative example for such a structure of the present exemplary embodiment, FIG. 5 illustrates a structure in which the underlying insulating film 102a is not provided in a region of a peripheral region from which the gate multilayer film (112, 113 and 114) has been removed. The processing dimension of an element-forming region, for example, a memory cell part is 0.1 μm or smaller when a gate multilayer film is processed by etching. In contrast, the processing dimension of an alignment mark part is several tens of micrometers to several hundreds of micrometers. Thus, the alignment mark part is far larger in the area of etching than the memory cell part. The etching rate of the alignment mark part is therefore so fast, compared with the memory cell part, that the gate oxide film 111 serving as a stopper may be penetrated through at least partially. This may cause even the silicon substrate to be etched and substrate damage 119 to occur. In that case, the shape of the mark deteriorates due to the substrate damage 119. If alignment is performed using this geometrically-deteriorated mark, there arises such a problem as difficulty in mark detection or degradation in alignment accuracy. In contrast, in the present exemplary embodiment, the underlying insulating film 102a is previously formed in the silicon substrate 101 within the peripheral region prior to forming the gate multilayer film (112, 113 and 114). Then, the gate multilayer film on this underlying insulating film 102a is etched. Consequently, etching can be stopped by the sufficiently thick underlying insulating film 102a. As a result, the depths of the mark holes 122a are kept uniform and damage to the silicon substrate 101 can be suppressed. Accordingly, it is possible to form a well-shaped alignment mark and obtain high alignment accuracy.

The underlying insulating film 102a in the peripheral region can be formed simultaneously with the element-isolating region (element-isolating insulating film) using an STI (Shallow Trench Isolation) technique. For example, the underlying insulating film 102a and the element-isolating region can be formed in the following way.

A first concave portion corresponding to the element-isolating region is formed in the silicon substrate and a second concave portion is formed in the peripheral region. An insulating film is formed so as to fill the first concave portion and the second concave portion. The insulating film outside the first concave portion and the second concave portion is removed. Thus, the element-isolating region is formed with the insulating film left inside the first concave portion and the underlying insulating film is formed with the insulating film left inside the second concave portion. The insulating film outside the first concave portion and the second concave portion can be removed by CMP (Chemical Mechanical Polishing) or by the combination of etching back and CMP.

The underlying insulating film 102a is preferably formed at least in a region of the peripheral region which corresponds to (coincides with) a region from which the gate multilayer film (112, 113 and 114) has been removed. That is, the gate multilayer film on the underlying insulating film 102a is preferably removed in part or in whole.

As described above, the underlying insulating film 102a in the peripheral region can be formed simultaneously with the element-isolating region (element-isolating insulating film). In addition, the removal of the gate multilayer film in the peripheral region can be achieved concurrently with the patterning of the gate multilayer film in the element-forming region by means of etching for the purpose of the patterning. Furthermore, the mark holes can be formed simultaneously with a contact hole in the element-forming region. As described above, according to the present exemplary embodiment, it is possible to simply and conveniently form an accurately detectable alignment mark, without having to add any new processes, change the processing conditions of existing processes, such as etching conditions, and make any design changes, such as a change in film thickness.

Next, a second exemplary embodiment will be described.

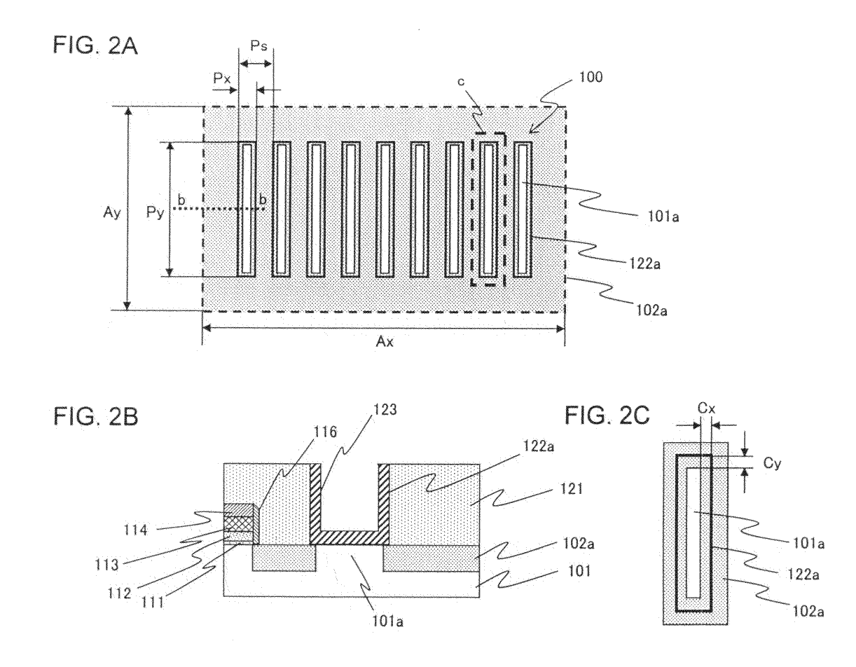

In the structure according to the first exemplary embodiment illustrated in FIG. 1, each mark hole 122a is formed so that the entire bottom-side opening of the mark hole is located above the underlying insulating film 102a. In contrast, in the second exemplary embodiment, a silicon part (isolated silicon part) 101a left without the underlying insulating film 102a being formed therein is located within the bottom-side opening region of the mark hole 122a, as illustrated in FIG. 2. That is, the peripheral border of the bottom-side opening of the mark hole 122a is located above the underlying insulating film 102a, and the isolated silicon part 101a is located on the inner side of the peripheral border (preferably at least the central part thereof).

Consequently, in the formation of the underlying insulating film 102a using an STI technique, it is possible to prevent dishing which can occur when an excess insulating film is removed by CMP. As a result, the depths of the mark holes can be made uniform even when a plurality of mark holes 122a is formed over a relatively wide region. Consequently, a contrast at the time of mark detection is kept constant (color irregularities are reduced) and alignment can be performed with higher accuracy.

Although etching damage is caused to a surface of the isolated silicon part 101a in the bottom of a mark hole, it is possible to also etch the silicon surface of the bottom of the mark hole at the time of performing Si etching on the bottom of a contact hole. Consequently, etching damage can be alleviated to the extent of being negligible in alignment.

Hereinafter, the above-described exemplary embodiments will be explained more specifically with reference to the accompanying drawings.

### Exemplary Embodiment 1

As illustrated in FIG. 1A, an alignment mark in the present exemplary embodiment includes nine mark holes 122a. The openings of these mark holes are arranged on lines and spaces, thereby forming a slit-like pattern. In this pattern, each mark hole 122a can be set so as to satisfy Px=6 μm, Py=70 μM, and Ps=12 μm. Px denotes the width of the opening of the mark hole 122a (short-side length: length in the lateral direction of the figure), Py denotes the long-side length of the mark hole 122a (length in the longitudinal direction of the figure), Ps denotes the array pitch of the mark holes 122a including Px.

As illustrated in FIG. 1B, a region (alignment mark-forming region) from which the gate multilayer film including the DOPOS film 112, the W film 114 and the gate mask nitride film 114 has been removed corresponds to the underlying insulating region (underlying insulating film) 102a. The underlying insulating region 102a (alignment mark-forming region) illustrated in FIG. 1A can be set so as to satisfy Ax=132 μm and Ay=75 μm. Ax denotes the length of the underlying insulating region (region from which the gate multilayer film has been removed) in the longitudinal direction thereof (lateral direction in the figure) and Ay denotes the length of the underlying insulating region in the latitudinal direction thereof (vertical direction in the figure).

As illustrated in FIG. 1A, the mark holes 122a are provided in the interlayer insulating film 121 within a region from which the gate multilayer film (112, 113 and 114) has been removed. Inside each of these mark holes 122a, there is formed the conductive film (DOPOS film) 123 made of a material the same as a contact plug material, so as not to fill the hole. A conductive film for wiring is formed so as not to fill this mark hole 122a, and lithographic alignment can be performed by taking advantage of a level difference created by a recess left inside this mark hole (level difference between the bottom of the recess and the peripheral border of the opening of the recess).

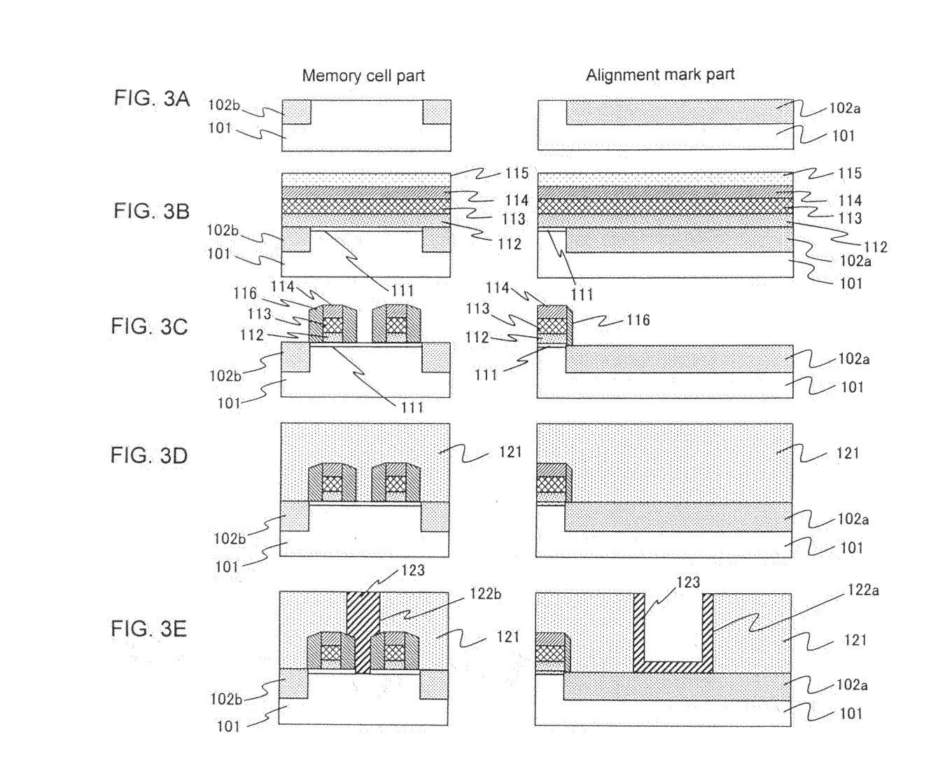

Hereinafter, a method for forming the above-described alignment mark will be described using FIG. 3.

Note that FIGS. 3A to 3E each illustrate cross sections of a structure in which a memory cell part in an element-forming region and an alignment mark part (corresponding to FIG. 1B) in a peripheral region are formed in a pair in the order of processes.

First, as illustrated in FIG. 3A, the element-isolating region (element-isolating insulating film) 102b of the memory cell part and the underlying insulating region (underlying insulating film) 102a of the alignment mark part are formed using an STI technique. The element-isolating region and the underlying insulating region can be formed in the following way. Using a lithography technique and an etching technique, concave portions corresponding to the element-isolating region and the underlying insulating region are respectively formed in predetermined regions of the silicon substrate 101. Then, a silicon oxide film is deposited using a CVD (Chemical Vapor Deposition) method, so as to fill these concave portions. After that, CMP is performed to remove an excess silicon oxide film outside these concave portions. Thus, it is possible to obtain insulating regions (element-isolating region 102b and underlying insulating region 102a) composed of the insulating film filled in the concave portions.

Next, as illustrated in FIG. 3B, a gate oxide film 111 is formed on a surface of the silicon substrate 101 using a thermal oxidation method. After that, a DOPOS film 112 is formed using a CVD method and a W film 113 is formed using a sputtering method. Then, a gate mask silicon nitride film 114 and a gate mask silicon oxide film 115 are formed using a CVD method. As a result, there is obtained a gate multilayer film including the DOPOS film 112, the W film 113, the gate mask silicon nitride film 114 and the gate mask silicon oxide film 115. The gate mask silicon nitride film 114 and the gate mask silicon oxide film 115 are utilized as hard masks in gate pattern formation. The gate mask silicon nitride film 114 is also utilized in forming a SAC (self-aligned contact) for a contact hole to be formed between gates.

Next, as illustrated in FIG. 3C, the gate multilayer film is processed using a lithography technique and a dry etching technique. A predetermined gate pattern is formed in the memory cell part of the element-forming region and a portion corresponding to the underlying insulating region is removed in the alignment mark part of the peripheral region. Next, a silicon nitride film is formed using a CVD method, and then the silicon nitride film is etched back to form a sidewall silicon nitride film 116. The gate mask oxide film 115 is etched away by processing up to this point.

Next, as illustrated in FIG. 3D, an interlayer insulating film 121 made of silicon oxide is formed using a CVD method. Then, CMP is performed to planarize the interlayer insulating film.

Next, a structure illustrated in FIG. 3E is formed in the following way. Using a lithography technique and a dry etching technique, a contact hole 122b, 70 nm in inner diameter, is formed in the memory cell part simultaneously with forming a mark hole 122a in the alignment mark part according to the layout illustrated in FIG. 1A (Px=6 μm, Py=70 μm, Ps=12 μm, Ax=132 μm, and Ay=75 μm).

After that, a 200 nm-thick DOPOS film 123 is formed using a CVD method, so as to fill the contact hole 122b but not to fill the mark hole 122a. Then, CMP is performed to remove an excess DOPOS film outside the contact hole 122b and the mark hole 122a. As a result, there is obtained a contact plug made of the DOPOS film inside the contact hole 122b. In addition, the concave portion remains inside the mark hole 122a, thereby obtaining a desired structure of the alignment mark part.

In order to achieve film formation so that the contact hole 122b is filled but the mark hole 122a is not filled, the mark hole 122a may be formed so as to have a minimum opening width sufficiently larger than the maximum opening width of the contact hole 122b. In addition, a film thickness at the time of film formation may be set large enough for the contact hole 122b to be filled up. At that time, the minimum opening width (for example, a short-side length in the case of a rectangular opening or a diameter in the case of a circular opening) of the mark hole may be set 10 times or more, preferably 20 times or more, more preferably 30 times or more, particularly preferably 50 times or more, as large as the maximum opening width (for example, a long-side length in the case of a rectangular opening or a diameter in the case of a circular opening) of the contact hole. In particular, the maximum opening width of the contact hole is preferably 100 nm or smaller. The minimum opening width of the mark hole is preferably made as much as possible larger than the maximum opening width of the contact hole. The minimum opening width may be set as appropriate, however, taking into consideration the occupation area and the like of the alignment mark.

After that, a conductive film for wiring is formed so as not to fill the mark hole 122a (i.e., not to fill the concave portion inside the mark hole 122a), thereby leaving the concave portion inside the mark hole 122a. In lithography, alignment can be performed by taking advantage of a contrast due to a level difference between the bottom of this eventually left-over concave portion and the peripheral border of the opening of the concave portion. After alignment is performed in this way, the conductive film for wiring is subjected to patterning.

### Exemplary Embodiment 2

In the present exemplary embodiment, the structures of the memory cell part and the alignment mark part can be formed in the same way as in the above-described exemplary embodiment, except that the isolated silicon part 101a is located within the bottom-side opening region of the mark hole 122a in a region of the peripheral region from which the gate multilayer film has been removed, as illustrated in FIG. 2.

FIG. 2C provides an enlarged view of a portion of FIG. 2A enclosed by a dotted line “c”. As illustrated in FIG. 2C, a positional relationship between the peripheral border of the bottom-side opening of the mark hole 122a and the isolated silicon part 101a inside this bottom-side opening can be defined as Cx=Cy=1 μm. By providing a margin between the peripheral border (border line) of the bottom-side opening of the mark hole 122a and the peripheral border (border line) of the isolated silicon part 101a, as described above, it is possible to keep the isolated silicon part 101a located inside the bottom-side opening of the mark hole 122a even if there is more or less a process variation.

It is apparent that the present invention is not limited to the above embodiments, but may be modified and changed without departing from the scope and spirit of the invention.

What is claimed is:

1. A semiconductor device manufacturing method comprising:
forming an element-isolating insulating film in an element-forming region of a semiconductor substrate and forming an underlying insulating film in a peripheral region outside the element-forming region;
forming a gate material film on the element-forming region and the peripheral region;
etching the gate material film to form a gate pattern in the element-forming region and removing the gate material film on the underlying insulating film to form an alignment mark-forming region in the peripheral region;
forming an interlayer insulating film on the element-forming region and the alignment mark-forming region;
etching the interlayer insulating film to form a contact hole penetrating the interlayer insulating film in the element-forming region and to form a mark hole penetrating the interlayer insulating film in the alignment mark-forming region;
forming a first conductive film so as to fill the contact hole but not to fill the mark hole;
removing the first conductive film outside the contact hole and the mark hole to form a contact plug inside the contact hole;
forming a second conductive film so as not to fill the mark hole, whereby leaving a recess inside the mark hole; and
performing lithographic alignment by taking advantage of a level difference created by the recess inside the mark hole after the formation of the second conductive film to pattern the second conductive film.

2. The semiconductor device manufacturing method according to claim 1, wherein the forming the element-isolating insulating film and the underlying insulating film includes:
forming a first concave portion in the element-forming region of the semiconductor substrate and forming a second concave portion in the peripheral region;
forming an insulating film so as to fill the first concave portion and the second concave portion; and
removing the insulating film outside the first concave portion and the second concave portion, whereby forming the element-isolating insulating film with the insulating film left inside the first concave portion and forming the underlying insulating film with the insulating film left inside the second concave portion.

3. The semiconductor device manufacturing method according to claim 1, wherein the forming the element-isolating insulating film and the underlying insulating film includes:
forming a first concave portion in the element-forming region of the semiconductor substrate and forming a second concave portion surrounding a surface part of the semiconductor substrate in the peripheral region such that the surface part of the semiconductor substrate remains inside the bottom-side opening of the mark hole;
forming an insulating film so as to fill the first concave portion and the second concave portion; and
removing the insulating film outside the first concave portion and the second concave portion by performing chemical-mechanical polishing, whereby forming the element-isolating insulating film with the insulating film left inside the first concave portion and forming the underlying insulating film with the insulating film left inside the second concave portion; and
wherein the mark hole is formed such that the surface part of the semiconductor substrate is located inside the bottom-side opening of the mark hole.

4. The semiconductor device manufacturing method according to claim 3, wherein a surface part of the semiconductor substrate in the bottom of the contact hole and the surface part of the semiconductor substrate in the bottom of the mark hole are simultaneously etched prior to forming the second conductive film.

5. The semiconductor device manufacturing method according to claim 1, wherein the gate material film includes a polysilicon film.

6. The semiconductor device manufacturing method according to claim 1, wherein the semiconductor substrate is a silicon substrate, the element-isolating insulating film and the underlying insulating film are formed of silicon oxide, and the gate material film includes a polysilicon film at least on the lowermost layer side thereof.

7. The semiconductor device manufacturing method according to claim 1, wherein the mark hole has a minimum opening width larger than the maximum opening width of the contact hole.

8. The semiconductor device manufacturing method according to claim 1, wherein one alignment mark is composed of a plurality of the mark holes.

9. The semiconductor device manufacturing method according to claim 8, wherein the planar shape of the mark holes is rectangular and the long sides thereof are arranged parallel to one another.
